(19) United States
(12) Patent Application Publication
(10) Pub. No.: US 2020/0075571 A1
(43) Pub. Date: Mar. 5, 2020

(54) SEMICONDUCTOR DEVICE PACKAGE AND METHOD OF MANUFACTURING THE SAME

(71) Applicant: Advanced Semiconductor Engineering, Inc., Kaohsiung (TW)

(72) Inventors: Chien-Hua CHEN, Kaohsiung (TW); Teck-Chong LEE, Kaohsiung (TW)

(73) Assignee: Advanced Semiconductor Engineering, Inc., Kaohsiung (TW)

(21) Appl. No.: 16/560,870

(22) Filed: Sep. 4, 2019

Related U.S. Application Data
(60) Provisional application No. 62/727,461, filed on Sep. 5, 2018.

(51) Int. Cl. H01L 25/18; H01L 23/31; H01L 23/495; H01L 21/56; H01L 21/48; H01L 23/66

(52) U.S. Cl. CPC H01L 25/18; H01L 23/3121; H01L 23/49575; H01L 23/49503; H01L 23/3135; H01L 21/56; H01L 24/24; H01L 23/49541; H01L 23/66; H01L 2223/6644; H01L 2223/6683; H01L 2223/6672; H01L 21/4853

(57) ABSTRACT

A semiconductor device package includes a carrier, an electronic component, a protection layer, a conductive layer and an integrated passive device (IPD). The electronic component is disposed on the carrier. The protection layer covers the carrier and the electronic component. The conductive layer is disposed on the protection layer and penetrates the protection layer to be electrically connected to the electronic component. The IPD is disposed on the conductive layer and electrically connected to the electronic component through the conductive layer.

### CROSS-REFERENCE TO RELATED APPLICATIONS

This application claims the benefit of and priority to U.S. Provisional Application No. 62/727,461, filed Sep. 5, 2018, the contents of which are incorporated herein by reference in their entirety.

### BACKGROUND

### 1. Technical Field

The present disclosure relates to a semiconductor device package and a method of manufacturing the same, and to a semiconductor device package including a passive element and a method of manufacturing the same.

### 2. Description of the Related Art

As the development of wireless communication techniques, monolithic microwave integrated circuits (MMIC) become more and more important. A power amplifier (PA) is one of the elements in the MIMIC for amplifying the power of a transmission signal. The MIMIC also includes one or more passive elements, such as an inductor, a capacitor, a resistor, a transformer and the like. In general, the passive elements may be integrated into a single package/chip/die (e.g., integrated passive device, IPD). It is challenging to integrate the IPD and the PA with the good capability of heat dissipation.

### SUMMARY

In accordance with some embodiments of the present disclosure, a semiconductor device package includes a carrier, an electronic component, a protection layer, a conductive layer and an integrated passive device (IPD). The electronic component is disposed on the carrier. The protection layer covers the carrier and the electronic component. The conductive layer is disposed on the protection layer and penetrates the protection layer to be electrically connected to the electronic component. The IPD is disposed on the conductive layer and electrically connected to the electronic component through the conductive layer.

In accordance with some embodiments of the present disclosure, a semiconductor device package includes a carrier, an IPD and an electronic component. The IPD is disposed on the carrier. The IPD has an active surface facing the carrier. The electronic component is disposed on the active surface of the IPD. The electronic component has an active surface facing the active surface of the IPD and electrically connected to the IPD.

In accordance with some embodiments of the present disclosure, a method of manufacturing a semiconductor device package includes (a) providing an IPD; (b) disposing one or more electrical contacts on an active surface of the IPD; (c) disposing an electronic component on the active surface of the IPD; and (d) forming a conductive layer electrically connecting to the electronic component and the electrical contacts.

### BRIEF DESCRIPTION OF THE DRAWINGS

FIG. 1A illustrates a cross-sectional view of a semiconductor device package in accordance with some embodiments of the present disclosure.

FIG. 1B illustrates a perspective view of an integrated passive device in accordance with some embodiments of the present disclosure.

FIG. 2 illustrates a cross-sectional view of a semiconductor device package in accordance with some embodiments of the present disclosure.

FIG. 3 illustrates a cross-sectional view of a semiconductor device package in accordance with some embodiments of the present disclosure.

FIG. 4A illustrates a cross-sectional view of a semiconductor device package in accordance with some embodiments of the present disclosure.

FIG. 4B illustrates a cross-sectional view of a semiconductor device package in accordance with some embodiments of the present disclosure.

FIG. 5 illustrates a cross-sectional view of a semiconductor device package in accordance with some embodiments of the present disclosure.

FIG. 6 illustrates a cross-sectional view of a semiconductor device package in accordance with some embodiments of the present disclosure.

FIG. 7A, FIG. 7B, FIG. 7C, FIG. 7D, FIG. 7E, FIG. 7F, FIG. 7G and FIG. 7H illustrate a method for manufacturing a semiconductor device package in accordance with some embodiments of the present disclosure.

FIG. 8A, FIG. 8B, FIG. 8C, FIG. 8D and FIG. 8E illustrate a method for manufacturing a semiconductor device package in accordance with some embodiments of the present disclosure.

Common reference numerals are used throughout the drawings and the detailed description to indicate the same or similar components. The present disclosure will be readily understood from the following detailed description taken in conjunction with the accompanying drawings.

### DETAILED DESCRIPTION

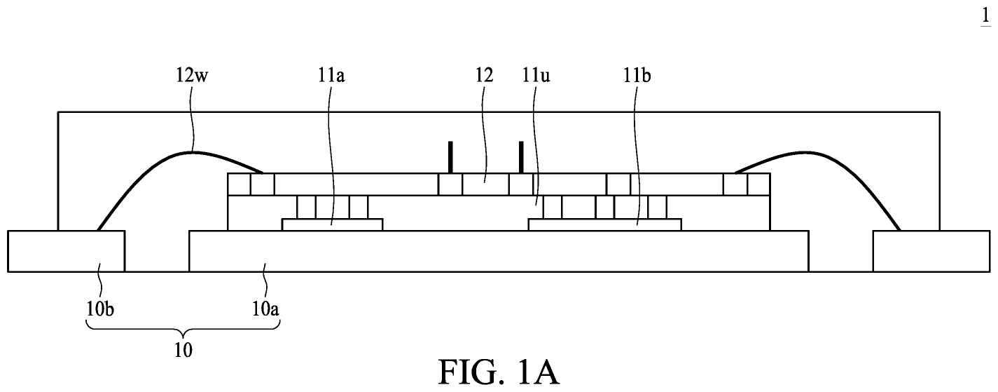

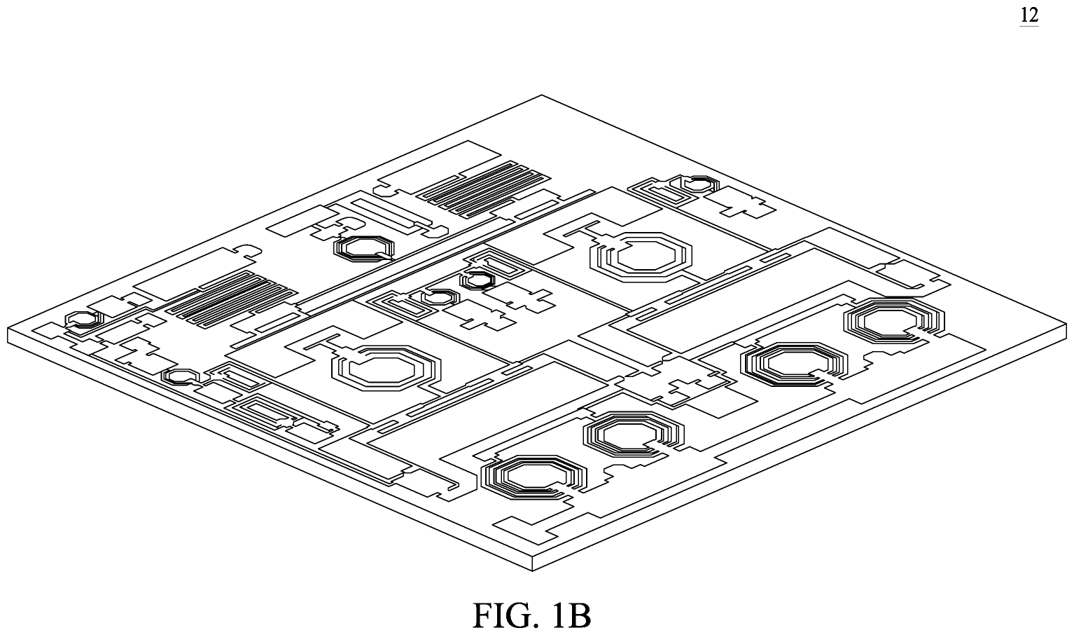

FIG. 1A illustrates a cross-sectional view of a semiconductor device package 1 in accordance with some embodiments of the present disclosure. The semiconductor device package 1 includes a leadframe 10, electronic components 11a, 11b and an integrated passive device (IPD) 12. In some embodiments, the semiconductor device package 1 in FIG. 1A is a Quasi-MMIC quad flat no-lead (QFN) package.

The leadframe 10 includes a die pad 10a and a plurality of leads 10b spaced apart from the die pad 10a. The electronic components 11a and 11b are disposed on the die pad 10a of the leadframe 10. In some embodiments, the electronic components 11a and 11b may include GaN Pseudomorphic High Electron Mobility Transistors (pHEMT) power amplifier (PA). In some embodiments the electronic components 11a and 11b are covered or encapsulant by an underfill 11u.

The IPD 12 is disposed on the underfill 11u and electrically connected to the electronic components 11a and/or 11b. For example, the IPD 12 may be electrically connected to electrodes or terminals of the electronic components 11a and/or 11b exposed from the underfill 11u. In some embodiments, the IPD 12 includes at least one of an inductor, a capacitor, a resistor and a transformer as shown in FIG. 1B, which illustrates a perspective view of the IPD 12. In some embodiments, the IPD 12 is a silicon-on-insulator (SOI) MMIC having through silicon vias (TSVs). The IPD 12 is electrically connected to the leads through conductive wires 12w (e.g., bonding wire). However, an additional space is included for accommodate the bonding wire 12w, and thus the use of the bonding wire 12w will hinder the miniaturization of the semiconductor device package 1.

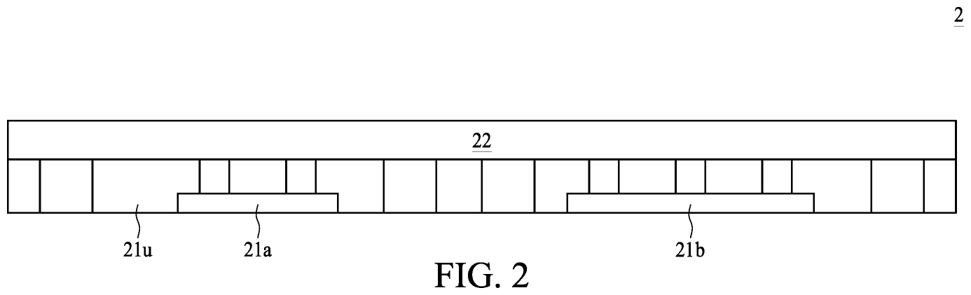

FIG. 2 illustrates a cross-sectional view of a semiconductor device package 2 in accordance with some embodiments of the present disclosure. The semiconductor device package 2 includes electronic components 21a, 21b and an IPD 22. In some embodiments, the semiconductor device package 2 in FIG. 2 is a Quasi-MMIC chip scale land grid array (LGA). Similar to the semiconductor device package 1 in FIG. 1A, the electronic components (GaN pHEMT PA) 21a and 21b in FIG. 2 are covered or encapsulant by an underfill 21u and electrically connected to the IPD 22. However, the chip scale LGA is unfavorable for heat dissipation of the electronic components 21a and 21b.

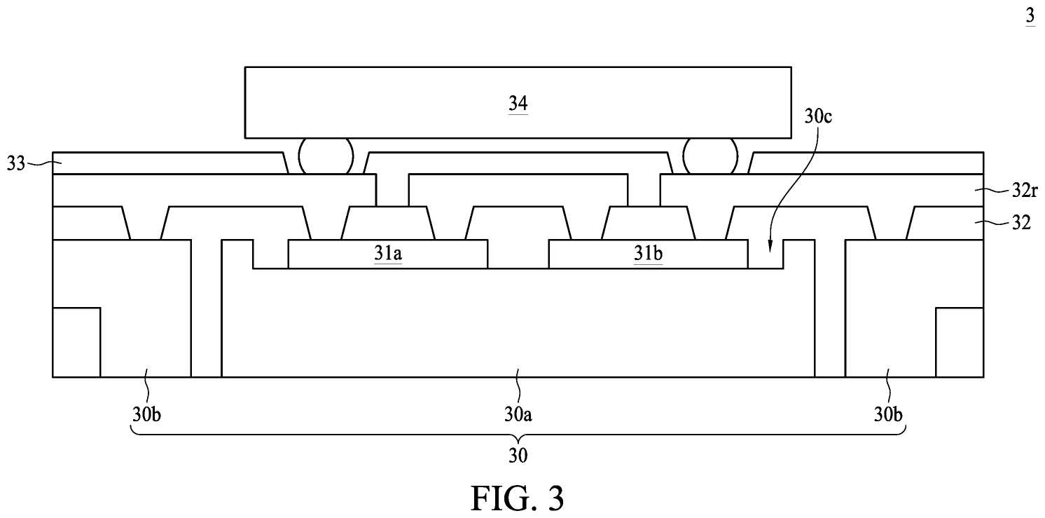

FIG. 3 illustrates a cross-sectional view of a semiconductor device package 3 in accordance with some embodiments of the present disclosure. The semiconductor device package includes a leadframe 30, electronic components 31a, 31b, a dielectric layer 32, a solder resist 33 and an IPD 34.

The leadframe 30 includes a die pad 30a (or die paddle) and a plurality of leads 30b. The die pad 30a has a cavity 30c (or recess) to accommodate the electronic components 31. The leads 30b are spaced apart from the die pad 30a and may be disposed at the periphery of the die pad 30a. In some embodiments, the leadframe 30 may include copper (Cu), copper alloy, iron/iron (Fe) alloy, nickel/nickel (Ni) alloy, or any other metal/metal alloy. In some embodiments, the leadframe 30 can be coated with a silver (Ag) layer. In some embodiments, the leadframe 30 may be replaced by a substrate depending on different design specifications.

The electronic components 31a and 31b are disposed within the cavity 30c of the die pad 30a of the leadframe 30. The electronic components 31a and 31b have backside surfaces facing the die pad 30a. In some embodiments, the backside surfaces of the electronic components 31a and 31b are in contact with the die pad 30a. In some embodiments, the backside surfaces of the electronic components 31a and 31b are connected to the die pad 30a through an adhesive layer (e.g., die attach film, DAF). The electronic components 31a and 31b are electrical connected to the leads through a conductive layer 32r (e.g., redistribution layer, RDL). In some embodiments, the electronic components 31a and 31b include GaN (or Silicon) pHEMT PA. In other embodiments, the electronic components 31a and 31b may include a gallium arsenide (GaAs) PA. In other embodiments, the electronic components 31a and 31b can be fabricated using an integrated bipolar-field effect transistor (BIFET) process utilizing a lower turn-on voltage of field effect transistors. Furthermore, in particular embodiments, the electronic components 31a and 31b may include bipolar junction transistors (referred to as a BJT), which includes heterojunction bipolar junction transistors (referred to as an HBT) and field effect transistors (referred to as a FET) that are fabricated using what is referred to as the BIFET or BiHEMT process.

The dielectric layer 32 covers the leadframe 30 and the electronic components 31a and 31b. The dielectric layer 32 has one or more openings (or recesses) to expose a portion of the electronic components 31a and 31b for electrical connections. In some embodiments, the dielectric layer 32 may include molding compounds, pre-impregnated composite fibers (e.g., pre-preg), Borophosphosilicate Glass (BPSG), silicon oxide, silicon nitride, silicon oxynitride, Undoped Silicate Glass (USG), glass, ceramic, any combination of two or more thereof, or the like. Examples of molding compounds may include, but are not limited to, an epoxy resin including fillers dispersed therein. Examples of a pre-preg may include, but are not limited to, a multi-layer structure formed by stacking or laminating a number of pre-impregnated materials/sheets.

The conductive layer 32r (e.g., redistribution layer, RDL) is disposed on the dielectric layer 32 and extends within the openings of the dielectric layer 31 to be electrically connected with the electronic components 31a and 31b. The conductive layer 32r is configured to provide electrical connections between electronic components 31a and 31b or between electronic components 31a and 31b and another circuit or element. In some embodiments, the conductive layer 32r may be configured to define an inductor, a transformer or an antenna. In this embodiment, the IPD 34 may be omitted depending on different design specifications. In some embodiments, there may be any number of conductive layers 32 depending on design specifications. In some embodiments, the conductive layer 32 is formed of or includes gold (Au), Ag, Cu, platinum (Pt), Palladium (Pd), other metal(s) or alloy(s), or a combination of two or more thereof.

The solder resist 33 covers the conductive layer 32r and the dielectric layer 32 for protecting the conductive layer 32r and the dielectric layer 32. The solder resist 33 has one or more openings (or recesses) to expose a portion of the conductive layer 32r for electrical connections.

The IPD 34 is disposed on the solder resist 33 and electrically connected to the conductive layer 32r through electrical contacts (e.g., solder balls). For example, the IPD 34 may be electrically connected to the conductive layer 32r through flip-chip technique. The IPD 34 is electrically connected to the electronic components 31a and 31b through the conductive layer 32r. For example, the IPD 34 may be electrically connected to electrodes or terminals of the electronic components 31a and 31b exposed from the dielectric layer 32. In some embodiments, the IPD 34 includes at least one of an inductor (e.g., two-dimensional inductor and/or three-dimensional inductor), a capacitor, a resistor and a transformer. In some embodiments, the IPD 34 is a SOI.

Since the IPD 34 and the electronic components 31a and 31b are electrically connected through the conductive layer 32r (e.g., RDL), the connection path therebetween is relatively short, which would reduce a resistance therebetween and then increase the electrical performance of the electronic components 31a and 31b (e.g., PA). In addition, the electronic components 31a and 31b are disposed within the cavity of the die pad 30a of the leadframe 30 and the backside surfaces of the electronic components 31a and 31b are connected to the die pad 30a, which would facilitate the thermal dissipation for the electronic components 31a and 31b.

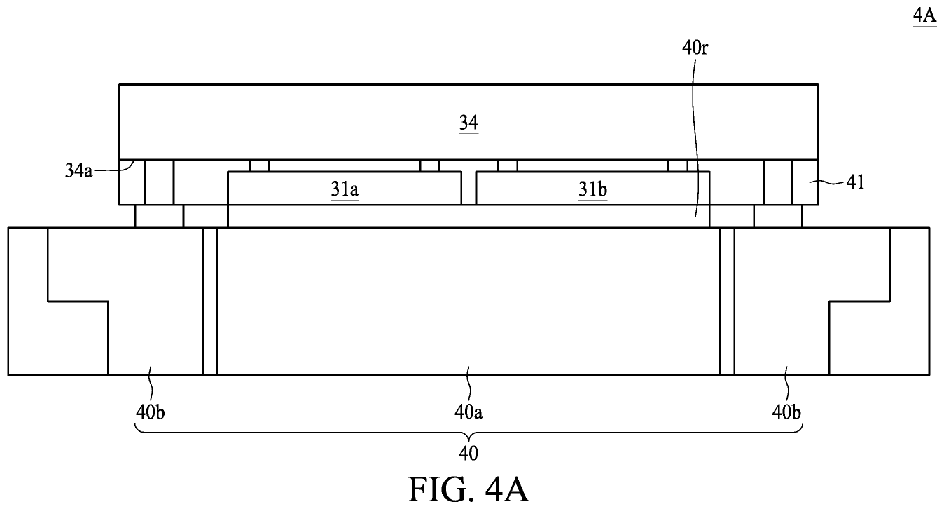

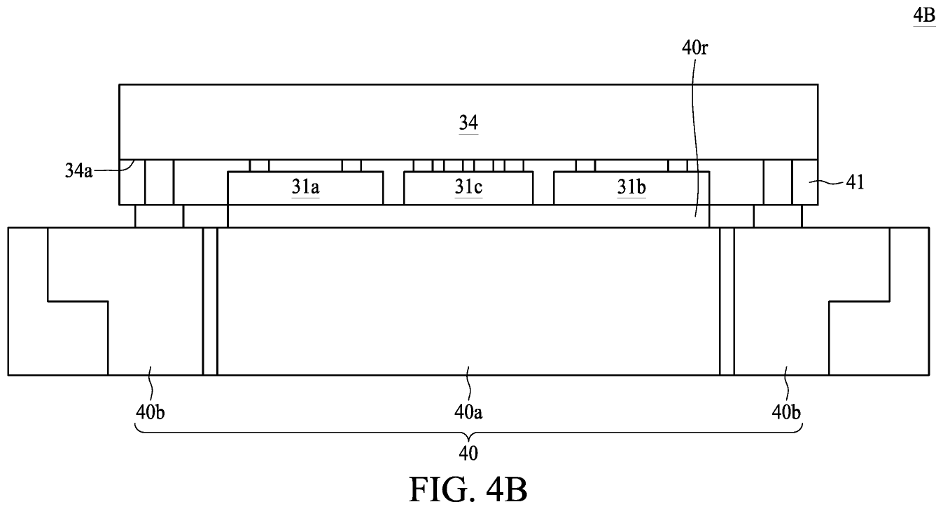

FIG. 4A illustrates a cross-sectional view of a semiconductor device package 4A in accordance with some embodiments of the present disclosure. The semiconductor device package 4A includes a leadframe 40 (including a die pad 40a and a plurality of leads 40b), electronic components 31a and 31b, the IPD 34 and a passivation layer 41. The leadframe 40 is similar to the leadframe 30 illustrated in FIG. 3 except that there is no cavity or recess formed on the die pad 40a of the leadframe 40. The electronic components 31a and 31b and the IPD 34 illustrated in FIG. 4A are similar to those illustrated in FIG. 3, and thus the descriptions of the electronic components 31a and 31b and the IPD 34 recited above are applicable to herein.

The electronic components 31a and 31b are disposed on an active surface 34a of the IPD 34. In some embodiments, the electronic components 31a and 31b are electrically connected to the IPD 34 through bumps or any other suitable elements. The IPD 34 is disposed on the leadframe 40 and electrically connected to the leads 40b of the leadframe 40 through conductive pillars or any other suitable conductive contacts. The IPD 34 is electrically connected to a conductive layer 40r (e.g., RDL) disposed on the leadframe 40 through the conductive pillars.

The passivation layer 41 covers the electronic components 31a and 31b and the conductive pillars connecting the IPD 34 with the conductive layer 40r. In some embodiments, the passivation layer 41 includes silicon oxide, silicon nitride, gallium oxide, aluminum oxide, scandium oxide, zirconium oxide, lanthanum oxide or hafnium oxide.

Since the electronic components 31a and 31b are directly disposed on the active surface 34a of the IPD 34, the connection path therebetween can be reduced, which will increase the electrical performance of the electronic components 31a and 31b. In addition, the thickness of the semiconductor device package 4A also can be reduced. Furthermore, the electronic components 31a and 31b (e.g., backside surfaces of the electronic components 31a and 31b) are attached to the conductive layer 40r, which will facilitate the thermal dissipation for the electronic components 31a and 31b.

FIG. 4B illustrates a cross-sectional view of a semiconductor device package 4B in accordance with some embodiments of the present disclosure. The semiconductor device package 4B illustrated in FIG. 4B is similar to the semiconductor device package 4A illustrated in FIG. 4A except that the semiconductor device package 4B in FIG. 4B further includes an electronic component 31c disposed on the active surface 34a of the IPD 34.

In some embodiments, the electronic component 31c can be a passive element (inductor/capacitor/resistor) or an active element (e.g., die/chip) depending on different design specifications. For example, if the capacitor within the IPD 34 is insufficient to provide a specified capacitance, the electronic component 31c can be an additional capacitor to increase the total capacitance to meet the specification. By further disposing the electronic component 31c on the active surface 34a of the IPD 34, the size of the semiconductor device package 4B can be further reduced and the design for the semiconductor device package 4B can be more flexible.

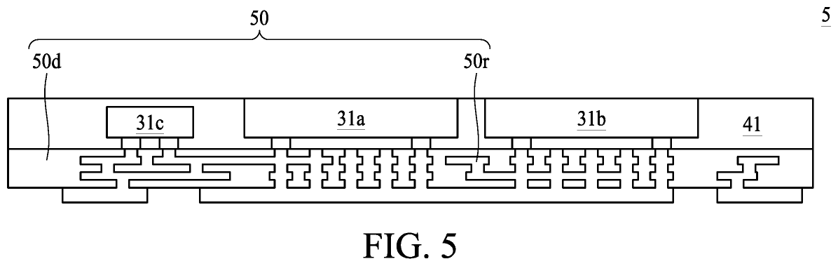

FIG. 5 illustrates a cross-sectional view of a semiconductor device package 5 in accordance with some embodiments of the present disclosure. The semiconductor device package 5 includes a circuit layer 50, electronic components 31a, 31b and 31c and a passivation layer 41. The electronic components 31a, 31b, 31c and the passivation layer 41 illustrated in FIG. 5 are similar to those illustrated in FIG. 4B, and thus the descriptions for parameters of the electronic components 31a, 31b, 31c and the passivation layer 41 recited above are applicable to herein.

The circuit layer 50 includes an interconnection layer (e.g., redistribution layer, RDL) 50r and a dielectric layer 50d. A portion of the interconnection layer 50r is covered or encapsulated by the dielectric layer 50d while another portion of the interconnection layer 50r is exposed from the dielectric layer 50d to provide electrical connections for the electronic components 31a, 31b and 31c. In some embodiments, the interconnection layer 50r includes an interconnection for the electronic components 31a, 31b and 31c and defines an inductor. In some embodiments, the circuit layer 50 can be a fan-out structure or a fan-in structure depending on different design specifications. In some embodiments, the inductor and the fan-out structure (or fan-in structure) are integrated into the circuit layer 50. For example, the circuit layer 50 defines a fan-out inductor.

In some embodiments, the dielectric layer 50d may include molding compounds, pre-impregnated composite fibers (e.g., pre-preg), Borophosphosilicate Glass (BPSG), silicon oxide, silicon nitride, silicon oxynitride, Undoped Silicate Glass (USG), any combination of two or more thereof, or the like. Examples of molding compounds may include, but are not limited to, an epoxy resin including fillers dispersed therein. Examples of a pre-preg may include, but are not limited to, a multi-layer structure formed by stacking or laminating a number of pre-impregnated materials/sheets.

As shown in the semiconductor device package in FIG. 4A, in which the IPD 34 is connected to the leadframe 40 and the electronic components 31a and 31b through conductive pillars (e.g., Cu pillar). In FIG. 5, the electronic components 31a, 31b, 31c or the inductor (which is integrated within the circuit layer 50) may connect to other circuits or circuit board through the interconnection layer 50r, which can reduce the manufacturing cost.

In addition, to integrate an inductor within an IPD, the thickness of the IPD is in a range from about 150 μm to about 200 μm. In accordance with the embodiments in FIG. 5, by using the circuit layer 50 to replace the IPD, the thickness of the circuit layer 50 can be reduced to about 60 μm to about 70 μm, which will reduce the total thickness of the semiconductor device package 5.

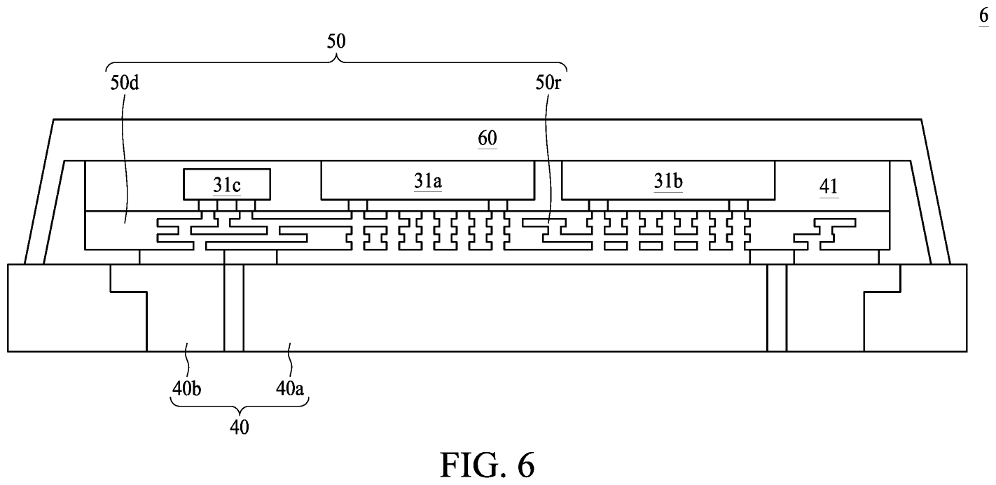

FIG. 6 illustrates a cross-sectional view of a semiconductor device package 6 in accordance with some embodiments of the present disclosure. The semiconductor device package 6 in FIG. 6 includes the semiconductor device package 5 in FIG. 5, a leadframe 40 and a heat sink 60. The semiconductor device package 5 as shown in FIG. 5 is disposed on the leadframe 40. The leadframe 40 illustrated in FIG. 6 are similar to those illustrated in FIG. 4B, and thus the descriptions for parameters of the leadframe 40 recited above are applicable to herein. The heat sink 60 is disposed on the leadframe 40 and in contact with the electronic components 31a and 31b (e.g., the backside surfaces of the electronic components 31a and 31b) to improve the heat dissipation of the semiconductor device package 6.

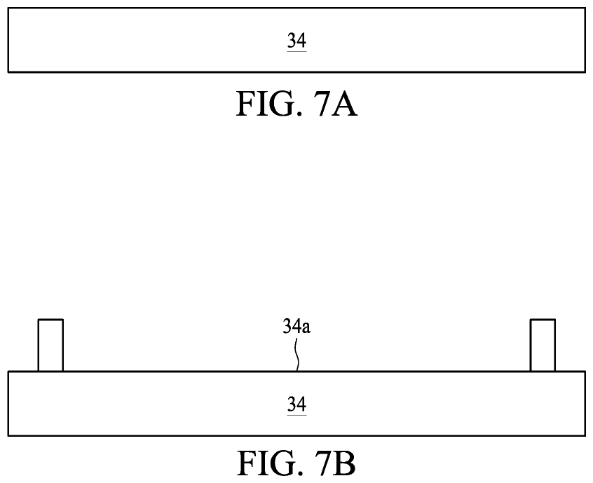

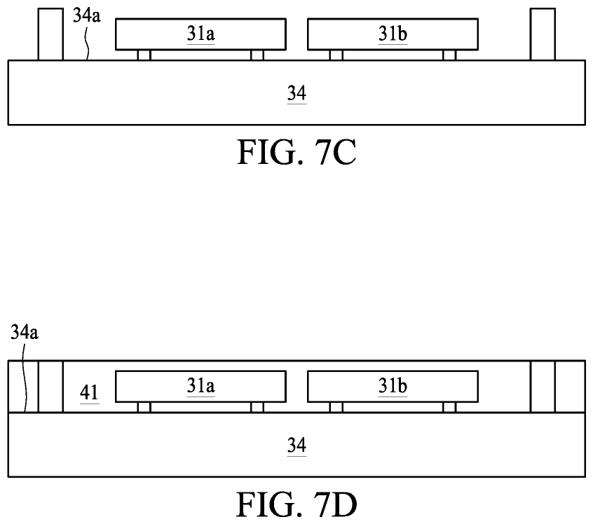

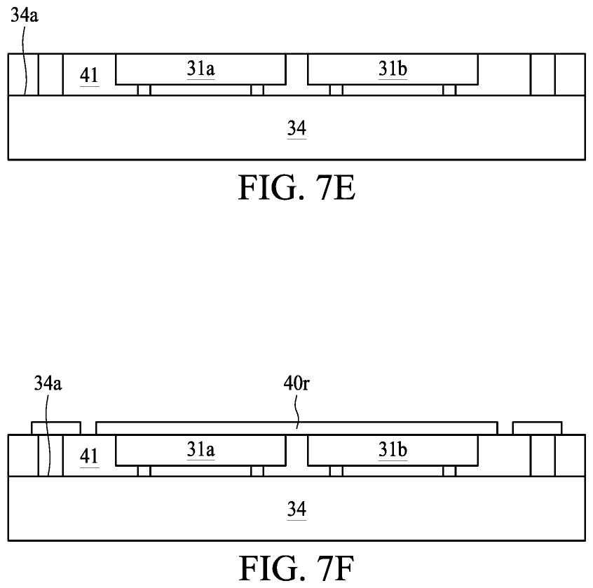

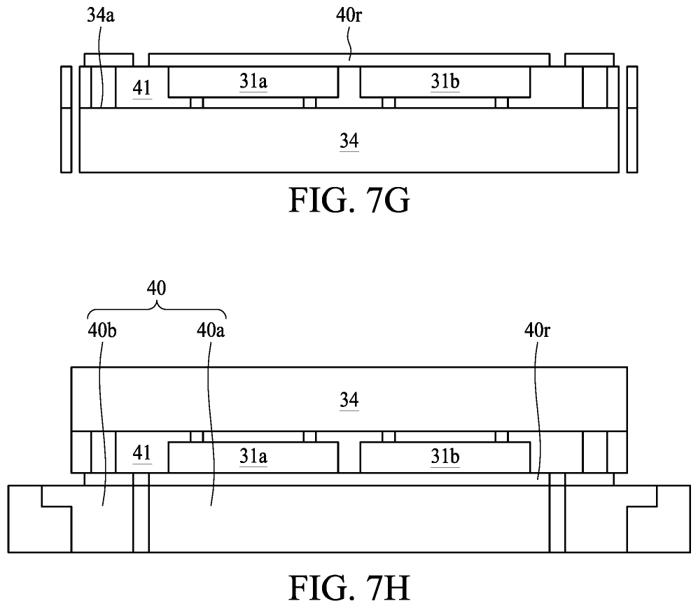

FIG. 7A, FIG. 7B, FIG. 7C, FIG. 7D, FIG. 7E, FIG. 7F, FIG. 7G and FIG. 7H illustrate a method for manufacturing a semiconductor device package in accordance with some embodiments of the present disclosure. In some embodiments, the method in FIG. 7A, FIG. 7B, FIG. 7C, FIG. 7D, FIG. 7E, FIG. 7F, FIG. 7G and FIG. 7H can be used to manufacture the semiconductor device package 4A as shown in FIG. 4A. Alternatively, the method in FIG. 7A, FIG. 7B, FIG. 7C, FIG. 7D, FIG. 7E, FIG. 7F, FIG. 7G and FIG. 7H can be used to manufacture other semiconductor device packages.

Referring to FIG. 7A, the IPD 34 or a series of IPD including the IPD 34 is provided. For example, an IPD wafer including the IPD 34 is provided. In some embodiments, the IPD wafer may have an 8-inch size or any other sizes.

Referring to FIG. 7B, one or more conductive pillars are formed on an active surface 34a of the IPD wafer including the IPD 34. Referring to FIG. 7C, the electronic components (e.g., chip/die including a PA) 31a and 31b are disposed on the active surface 34a of the IPD wafer including the IPD 34.

Referring to FIG. 7D, the passivation layer 41 is formed on the active surface 34a of the IPD 34 to cover the conductive pillars and the electronic components 31a and 31b. Referring to FIG. 7E, a portion of the passivation layer 41 is removed to expose the conductive pillars and the electronic components 31a and 31b. In some embodiments, the passivation layer 41 can be removed by grinding, etching or any other suitable processes. In some embodiments, a portion of the conductive pillars and a portion of the backside of the electronic components 31a and 31b may be removed as well. The conductive pillars, the electronic components 31a, 31b and the passivation layer 41 can be removed in a single process or in multiple processes depending on different embodiments.

Referring to FIG. 7F, the conductive layer 40r (e.g., RDL) is formed on the exposed portion of the conductive pillars and the electronic components 31a and 31b by, for example, sputtering, coating, plating or any other suitable processes.

Referring to FIG. 7G, singulation (or dicing) may be performed to separate out individual semiconductor package devices. That is, the singulation is performed through the passivation layer 41 and the IPD wafer including the IPD 34. The singulation may be performed, for example, by using a dicing saw, laser or other appropriate cutting technique.

Referring to FIG. 7H, the individual or divided semiconductor device package is disposed on the leadframe 40 or a substrate to form the semiconductor device package 4A as shown in FIG. 4A by, for example, flip-chip technique.

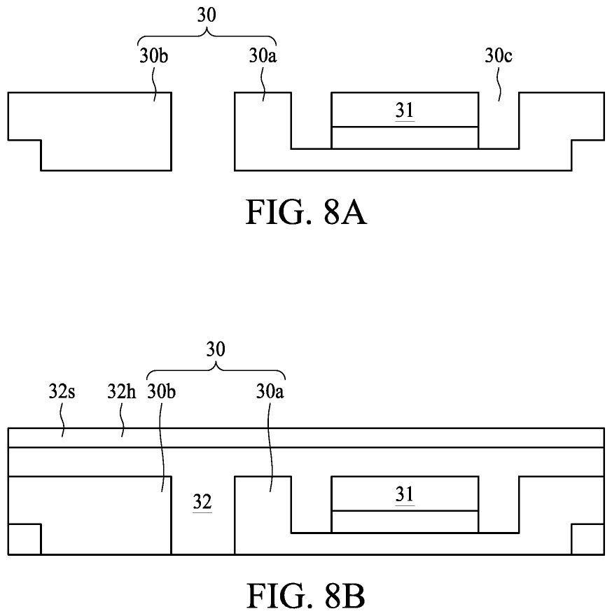

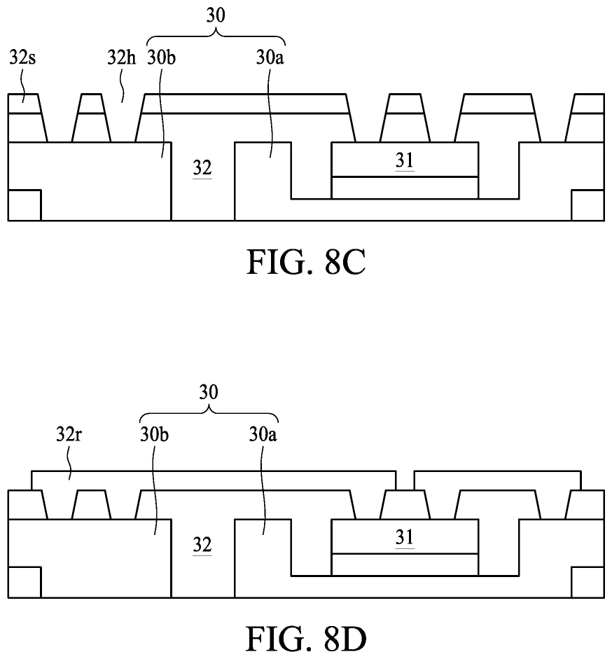

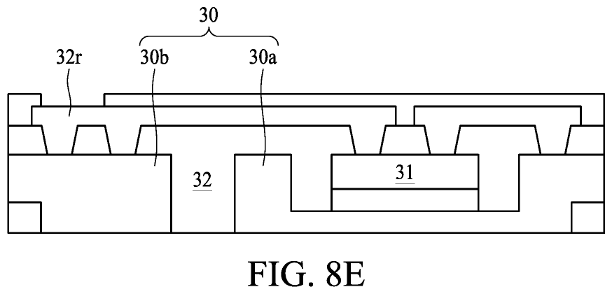

FIG. 8A, FIG. 8B, FIG. 8C, FIG. 8D and FIG. 8E illustrate a method for manufacturing a semiconductor device package in accordance with some embodiments of the present disclosure. In some embodiments, the method in FIG. 8A, FIG. 8B, FIG. 8C, FIG. 8D and FIG. 8E can be used to manufacture the semiconductor device package as shown in FIG. 3 or parts of the semiconductor device package as shown in FIG. 3. Alternatively, the method in FIG. 8A, FIG. 8B, FIG. 8C, FIG. 8D and FIG. 8E can be used to manufacture other semiconductor device packages.

Referring to FIG. 8A, the leadframe 30 or a leadframe strip including the leadframe 30 is provided. The cavity 30c is formed from a top surface of the die pad 30a into the die pad 30. The electronic component 31 is disposed or attached within the cavity 30c of the die pad 30a of the leadframe 30.

Referring to FIG. 8B, the protection layer 32 (e.g., dielectric layer, molding compound or passivation layer) is formed to cover the leadframe 30 and the electronic component 31 by, for example, lamination or any other suitable processes. A conductive layer 32s (e.g., a seed layer) is then formed on the protection layer 32 by, for example, coating, sputtering, plating or any other suitable processes.

Referring to FIG. 8C, one or more openings 32h are formed on the conductive layer 32s and the protection layer 32 to expose a portion of the leadframe 30 (e.g., to expose the leads 30b of the leadframe 30) and the electronic component 31 (e.g., to expose an active surface of the electronic component 31). In some embodiments, the openings 32h are formed by, for example, laser drilling, etching or any other suitable processes.

Referring to FIG. 8D, a conductive layer 32r (e.g., RDL) is formed on the conductive layer 32s and the exposed portion of the leadframe 30 and the electronic component 31 by, for example, plating or any other suitable processes. The conductive layer 32r connects the electronic component 31 with the leads 30b of the leadframe 30.

Referring to FIG. 8E, the solder resist 33 (or solder mask) is formed on the conductive layer 32r, and one or more openings are formed to expose a portion of the conductive layer 32r for electrical connections. In some embodiments, singulation (or dicing) may be performed to separate out individual semiconductor package devices. That is, the singulation is performed through the solder resist 33, the protection layer 32 and the leadframe strip including the leadframe 30. The singulation may be performed, for example, by using a dicing saw, laser or other appropriate cutting technique.

As used herein, the terms “substantially,” “substantial,” “approximately,” and “about” are used to denote and account for small variations. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. As another example, a thickness of a film or a layer being “substantially uniform” can refer to a standard deviation of less than or equal to ±10% of an average thickness of the film or the layer, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 within 30 within 20 within 10 or within 1 μm of lying along the same plane. Two surfaces or components can be deemed to be “substantially perpendicular” if an angle therebetween is, for example, 90°±10°, such as ±5°, ±4°, ±3°, ±2°, ±1°, ±0.5°, ±0.1°, or ±0.05°. When used in conjunction with an event or circumstance, the terms “substantially,” “substantial,” “approximately,” and “about” can refer to instances in which the event or circumstance occurs precisely, as well as instances in which the event or circumstance occurs to a close approximation.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It can be understood that such range formats are used for convenience and brevity, and should be understood flexibly to include not only numerical values explicitly specified as limits of a range, but also all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It can be clearly understood by those skilled in the art that various changes may be made, and equivalent elements may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. A semiconductor device package, comprising:
a carrier;
an electronic component disposed on the carrier,
a protection layer covering the carrier and the electronic component;
a conductive layer disposed on the protection layer and penetrating the protection layer to be electrically connected to the electronic component; and
an integrated passive device (IPD) disposed on the conductive layer and electrically connected to the electronic component through the conductive layer.

2. The semiconductor device package of claim 1, wherein the carrier is a leadframe or a substrate.

3. The semiconductor device package of claim 2, wherein the leadframe comprises a die pad and a plurality of leads spaced apart from the die pad, and the electronic component is disposed on the die pad and electrically connected to the leads through the conductive layer.

4. The semiconductor device package of claim 3, wherein the die pad includes a cavity to accommodate the electronic component.

5. The semiconductor device package of claim 1, wherein the conductive layer defines an inductor or a transformer.

6. The semiconductor device package of claim 1, wherein the electronic component includes a power amplifier (PA).

7. The semiconductor device package of claim 1, wherein the electronic component has an active surface facing an active surface of the IPD.

8. The semiconductor device package of claim 1, further comprising a solder resist cover a portion of the protection layer and a portion of the conductive layer.

9. A semiconductor device package, comprising:
a carrier;
an IPD disposed on the carrier, the IPD having an active surface facing the carrier; and
an electronic component disposed on the active surface of the IPD, the electronic component having an active surface facing the active surface of the IPD and electrically connected to the IPD.

10. The semiconductor device package of claim 9, wherein the carrier is a leadframe or a substrate.

11. The semiconductor device package of claim 10, wherein the leadframe comprising a die pad and a plurality of leads spaced apart from the die pad, the electronic component is disposed on the die pad, and the IPD is electrically connected to the leads through an electrical contact.

12. The semiconductor device package of claim 11, further comprising a passivation layer covering the electrical contact and the electronic component.

13. The semiconductor device package of claim 11, further comprising a conductive layer disposed between the leadframe and a backside surface of the electronic component.

14. The semiconductor device package of claim 9, wherein the electronic component includes a PA.

15. The semiconductor device package of claim 9, further comprising a capacitor disposed on the active surface of the IPD.

16. A method of manufacturing a semiconductor device package, the method comprising
(a) providing an IPD;
(b) disposing one or more electrical contacts on an active surface of the IPD;
(c) disposing an electronic component on the active surface of the IPD; and
(d) forming a conductive layer electrically connecting to the electronic component and the electrical contacts.

17. The method of claim 16, after operation (c) further comprising:
forming a protection layer to cover the electrical contacts and the electronic components;
removing a portion of the protection layer to expose a portion of the electrical contacts and the electronic components; and
forming the conductive layer in contact with the exposed portion of the electrical contacts and the electronic components.

18. The method of claim 16, further comprising connecting the IPD to a carrier.

19. The method of claim 18, wherein the carrier is a leadframe or a substrate.

20. The method of claim 16, wherein the electronic component includes a PA.
